(19) United States
(12) Patent Application Publication
(10) Pub. No.: US 2026/0138867 A1
(43) Pub. Date: May 21, 2026

(54) METHOD FOR PRODUCING A MICROMECHANICAL LAYER STRUCTURE WITH HIGH ASPECT RATIO AND MICROMECHANICAL LAYER STRUCTURE

(71) Applicant: Robert Bosch GmbH, Stuttgart (DE)

(72) Inventor: Christoph Schelling, Stuttgart (DE)

(21) Appl. No.: 19/109,218

(22) PCT Filed: Aug. 9, 2023
(86) PCT No.: PCT/EP2023/072025

§ 371 Date: Jan. 29, 2026

(30) Foreign Application Priority Data
Oct. 18, 2022 (DE) 10 2022 210 972.4

(51) Int. Cl. B81C 1/00; B81B 3/00

(52) U.S. Cl. CPC B81C 1/00619; B81B 3/0021; B81B 2201/02; B81B 2203/04; B81C 2201/0104; B81C 2201/0105; B81C 2201/0118; B81C 2201/0132; B81C 2201/014; B81C 2201/0174

(57) ABSTRACT

A method for producing a micromechanical layer structure with a high aspect ratio of a layer thickness to a distance of a first structural element from an adjacent second structural element in a main direction of extent of the layer structure. The method including: providing a substrate with an etching stop layer and a micromechanical functional layer; forming at least one recess in the functional layer by etching as far as the etching stop layer; depositing an intermediate layer sequence including a first insulation layer, an intermediate layer, and a second insulation layer; filling the recess by depositing a filling layer; planarizing the surface of the filling layer; etching the intermediate layer by etching access points through the intermediate layer sequence; exposing the first and second structural elements by etching the first insulation layer and the second insulation layer by a second etching process.

### BACKGROUND INFORMATION

Conventional capacitive MEMS actuators and sensors have the disadvantage that they are highly area-intensive. Comparatively large surface areas are required to achieve high forces, deflections or measurement signals in the substrate plane. Today, MEMS electrode combs are produced by directly etching a conductive electrode layer. Thus, the maximum capacitance density is limited by the aspect ratio of the electrode gap of approximately<30:1 (etch depth:etch trench width) that can be achieved with DRIE etching.

However, for MEMS loudspeakers as described in Germany Patent Application No. DE 10 2019 203 914, energy-efficient actuators with a very high aspect ratio (HAR) and thus high force density are required. The force density can be increased by increasing the aspect ratio of the electrode height to the width of the electrode gap.

PCT Patent Application No. WO 2007/8541 describes a nanoelectric drive (NED) actuator, the production of which is, however, very challenging. Due to the achievable aspect ratios in DRIE etching, such NED actuators with electrode spacings of ˜2.5 μm can conventionally only be produced up to a height of less than approximately 75 μm, as described in the article by B. Kaiser, S. Langa, L. Ehrig, et al., “Concept and proof for an all-silicon MEMS micro speaker utilizing air chambers.” Microsystems and Nanoengineering 5, 43 (2019).

### SUMMARY

An object of the present invention is the production of electrostatic MEMS electrode gaps having an aspect ratio of >30:1 (etch depth:etch trench width) that exceeds the previous related.

The present invention relates to a method for producing a micromechanical layer structure with a high aspect ratio of a layer thickness to a distance of a first structural element from an adjacent second structural element in a main direction of extent of the layer structure. According to an example embodiment of the present invention, the method includes the steps of:
(A) providing a substrate with an etching stop layer arranged thereon and a micromechanical functional layer arranged above the etching stop layer;
(B) forming at least one recess in the functional layer by etching as far as the etching stop layer;
(C) depositing an intermediate layer sequence comprising at least a first insulation layer, an intermediate layer and a second insulation layer;
(D) filling the recess by depositing a filling layer;
(E) planarizing the surface of the filling layer;
(F) etching the intermediate layer by etching access points through the intermediate layer sequence by a first etching process; and
(G) exposing the first structural element and the second structural element by etching the first insulation layer and the second insulation layer by a second etching process.

The above-mentioned object may be achieved by the method according to the present invention, because it makes it possible to produce micromechanical structures, in particular freely movable micromechanical structures, with a very high aspect ratio.

The method can be used advantageously, for example, for the production of NED actuators, for example in MEMS loudspeakers. The present invention therefore also relates to a micromechanical layer structure with a high aspect ratio and to a capacitive sensor and a capacitive actuator having such a layer structure.

### BRIEF DESCRIPTION OF THE DRAWINGS

FIG. 1 schematically shows a micromechanical device with anisotropically etched structures in the related art.

FIG. 2A to 2J show the method according to the present invention for producing a device having a micromechanical structure with a high aspect ratio using a device in various stages of manufacture in a first exemplary embodiment.

FIG. 3A to 3C show the method according to the present invention in a second exemplary embodiment.

FIG. 4 schematically shows the method according to the present invention for producing a device having a micromechanical structure with a high aspect ratio.

FIG. 5 shows an alternative design of the method step in FIG. 2C.

### DETAILED DESCRIPTION OF EXAMPLE EMBODIMENTS

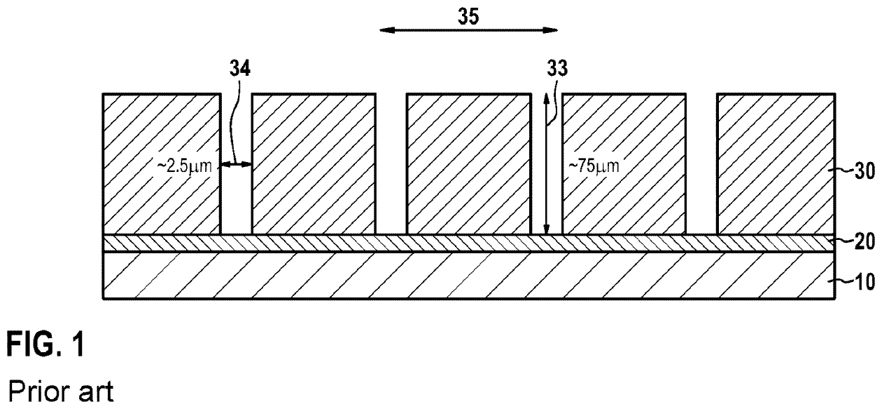

FIG. 1 schematically shows a micromechanical device with anisotropically etched structures in the related art. An etching stop layer 20 is deposited above a substrate 10, and a micromechanical functional layer 30 is deposited above the etching stop layer. The micromechanical functional layer has a height of ˜75 μm. By means of an anisotropic DRIE etching process (DRIE—deep reactive ion etch), narrow trenches of ˜2.5 μm width are created in the micromechanical functional layer. Thus, anisotropic etching makes an aspect ratio of 30:1 (height to width) possible. The device thus comprises electrodes 32 with a height of 75 μm and electrode gaps 35 with a width of 2.5 μm.

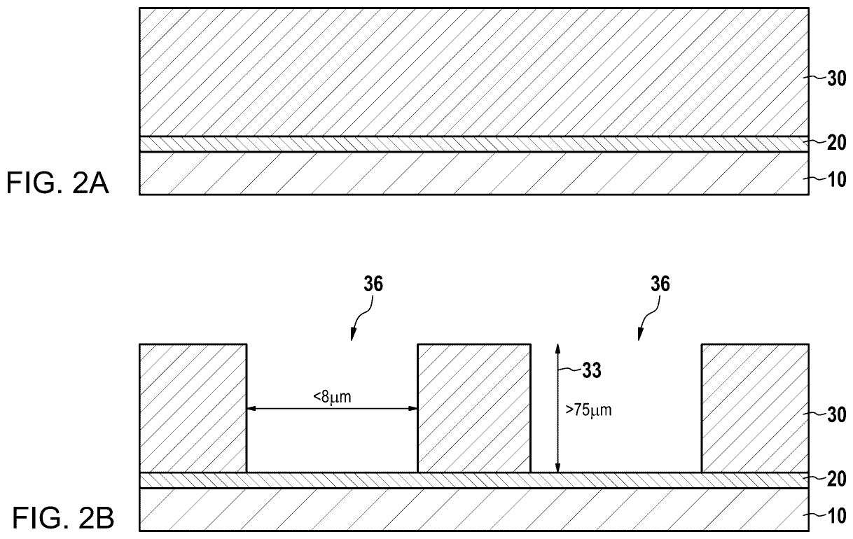

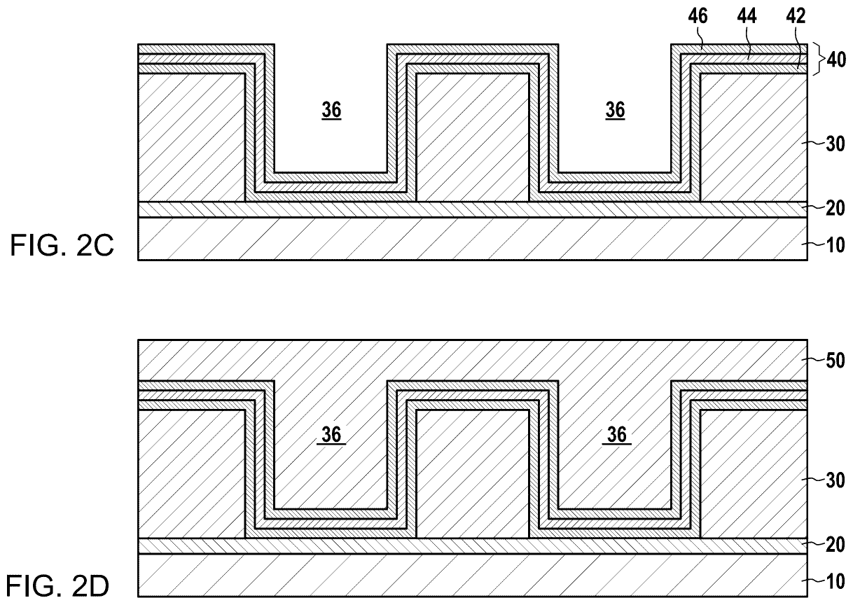

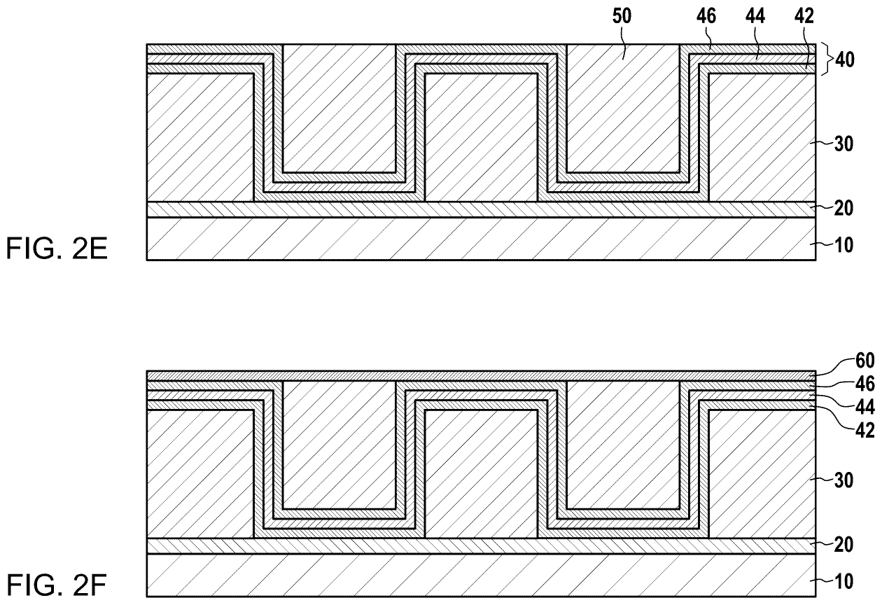

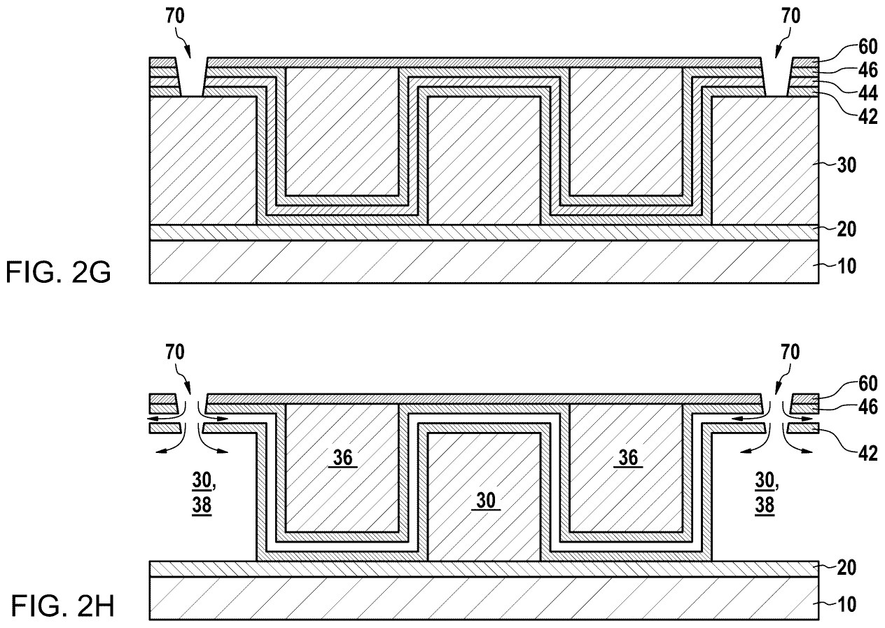

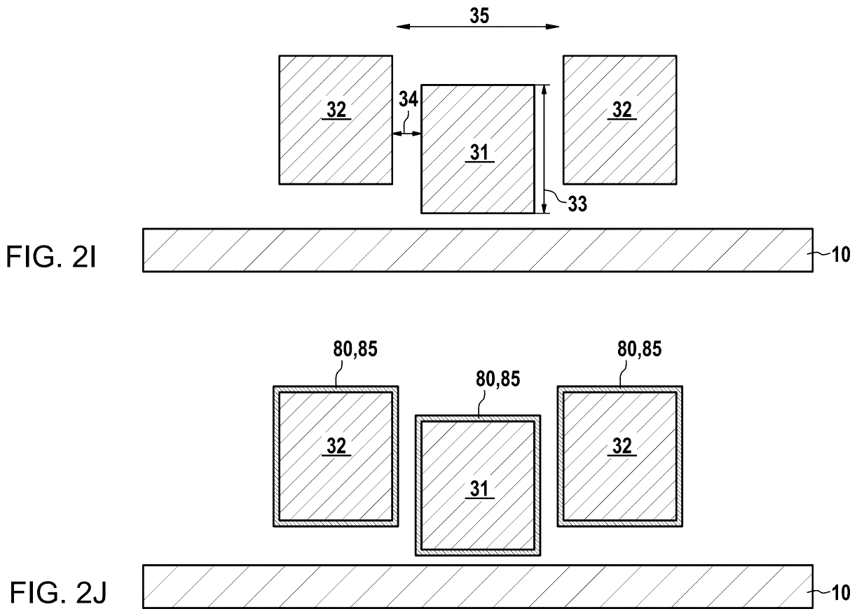

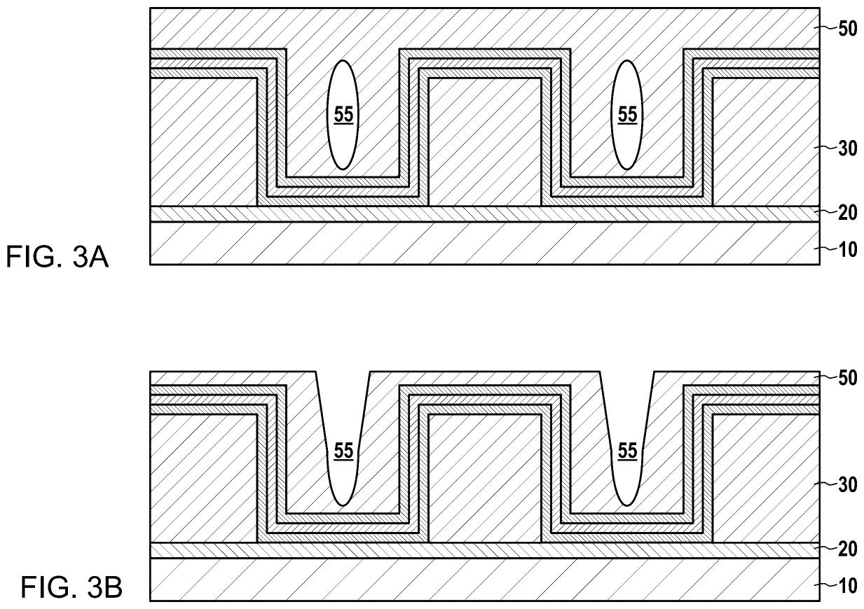

FIG. 2A to 2J show the method according to the present invention for producing a device having a micromechanical structure with a high aspect ratio using a device in various stages of manufacture in a first exemplary embodiment. The production of a MEMS electrode pair, for example for a MEMS actuator, is shown.

FIG. 2A shows the provision of a substrate 10 with at least one buried, preferably insulating etching stop layer 20 or sacrificial layer having a thickness of 0.5-2.5 μm and a micromechanical functional layer 30 having a thickness of 20-800 μm. The etching stop layer helps to precisely define the electrode height of the MEMS actuator. At the same time, the etching stop layer 20 can serve as a sacrificial layer for exposing the functional layer 30. Furthermore, in the regions remaining after the time-controlled sacrificial layer etching, the etching stop layer serves for anchoring and isolating the functional regions from the substrate.

A recess 36 is etched into the functional layer at the points provided for at least one filling or electrode as far as the etching stop layer (FIG. 2B). The functional layer has a thickness of >75 μm, and the recess has a width of <8 μm. The width of the recess corresponds to the provided width of an electrode plus twice the desired electrode distance.

An intermediate layer sequence 40 consisting of a first insulation layer 42 having a layer thickness of 10-2000 nm, an intermediate layer 44 having a thickness of 50-5000 nm and a second insulation layer 46 having a thickness of 10-2000 nm is then deposited (FIG. 2C). The two insulation layers can be formed by SiO2, for example, and deposited by means of LPCVD-TEOS or thermal oxidation. For the intermediate layer 44, for example, polysilicon deposited by LPCVD may be considered.

Subsequently, a filling layer 50 is deposited, which now fills the originally etched recess 36 as completely as possible and without voids (FIG. 2D). For example, conductive polysilicon, tungsten, etc. can be used as a filling layer for an electrode. Alternatively, silicon-rich nitride is also possible for purely mechanical functions.

FIG. 2E shows the planarization of the surface and the partial exposure of the buried intermediate layer sequence 40 by means of chemical-mechanical polishing (CMP).

Optionally, other important (auxiliary or functional) layers 60 for the functionality of the component, such as a hard mask, electrical contact layers or bond layers, can be applied and structured in this state (FIG. 2F). The previously applied layers of the intermediate layer sequence can also be structured, for example in order to limit sacrificial layer regions, make electrical contacting possible, etc.

FIG. 2G shows that etching access points 70 to the defined sacrificial regions 38 in the micromechanical functional layer 30 and the intermediate layer 44 are subsequently created, if not already present.

In a first sacrificial layer etching step, the sacrificial regions of the mechanical functional layer 30 and the intermediate layer 44 provided for this purpose are removed (FIG. 2H). This can be done by means of SF6 or XeF2 etching, for example. The advantage here is the large achievable under-etching width compared to slow HF gas phase etching.

Finally, the remaining sacrificial regions of the first and second insulation layers 42, 46 and the etching stop layer 20 provided for removal are removed using a second sacrificial layer etching process FIG. 2I). This can be, for example, HF gas phase etching. Due to the previous removal of the intermediate layer 44, a cavity is created that makes possible an immediate HF gas phase etching on the entire cavity surface, even with large under-etch widths, which considerably simplifies the exposure. The method can be used to produce electrode pairs that are approximately >75 . . . 800 μm high with an approximately 100 nm-10 μm electrode gap, whereas the method according to the related art can only produce electrode gaps that are <75 μm high and >2.5 μm wide.

Alternative exemplary embodiments of the production method according to the present invention are feasible.

After etching the recess in the functional layer (FIG. 2B), the surface can be smoothed, for example by tempering (thermal annealing).

If necessary, the electrode gap can be further narrowed by depositing conductive material in the form of an electrically conductive layer 80 on the electrodes after the sacrificial layer etching. Alternatively or additionally, a surface passivation in the form of a passivation layer 85 of, e.g., Al2O3/SiO2 can be deposited by means of ALD (atomic layer deposition) in order to protect the surface. (FIG. 2J).

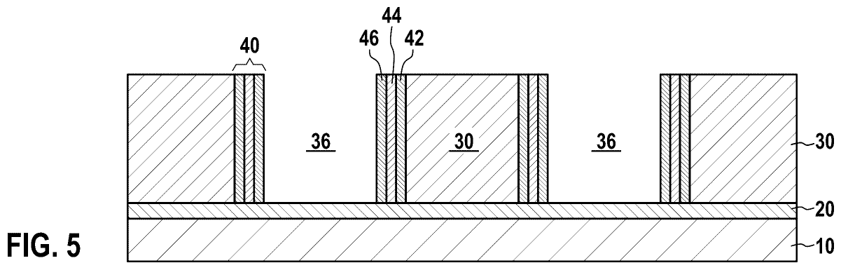

After deposition of the layers of the intermediate layer sequence, some or all of these layers can optionally be anisotropically etched back, wherein they are removed from horizontal regions and remain on the side walls of the recess. FIG. 5 shows an alternative design of the method step in FIG. 2C. Shown is the deposition of an intermediate layer sequence 40 consisting of a first insulation layer 42, an intermediate layer 44 and a second insulation layer 46, for example a lower oxide, a polysilicon and an upper oxide, wherein each of the layers is anisotropically etched back after deposition. The result is a structure on the side walls of recess 36 that defines the width of the electrode gap to be created.

When depositing the filling layer, as shown in FIG. 2D, the inclusion of voids may result.

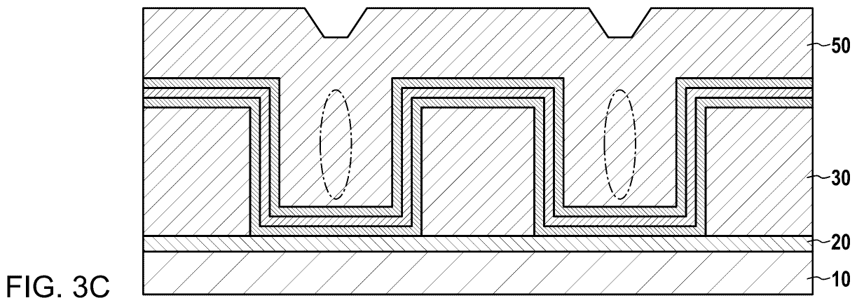

FIG. 3a to c show the method according to the present invention in a second exemplary embodiment, wherein voids are removed or avoided.

FIG. 3A shows the deposition of a filling layer 50 made of polysilicon, analogous to FIG. 2D. Voids 55 can be included, usually centrally.

Therefore, the filling layer 50 is partially etched back in the next step and the voids 55 are opened in the process (FIG. 3B).

A further layer of the filling layer 50 is then deposited. The voids 55 are filled and disappear (FIG. 3C).

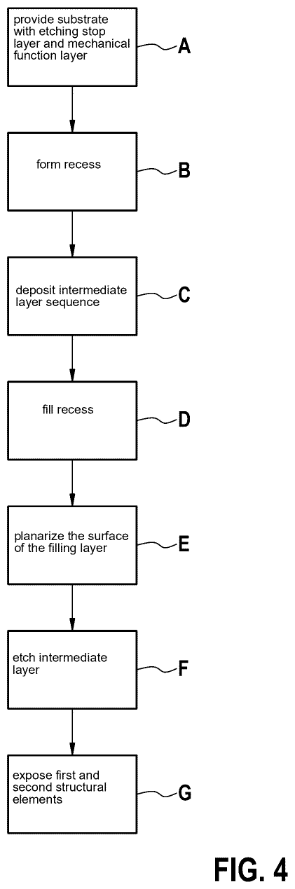

In summary, FIG. 4 schematically shows the method according to the present invention for producing a device having a micromechanical structure with a high aspect ratio.

The method comprises the following necessary steps:
(A) providing a substrate 10 with an etching stop layer 20 arranged thereon and a micromechanical functional layer 30 arranged above the etching stop layer;
(B) forming at least one recess 36 in the functional layer 30 by etching as far as the etching stop layer 20;
(C) depositing an intermediate layer sequence 40 comprising at least a first insulation layer 42, an intermediate layer 44 and a second insulation layer 46;
(D) filling the recess 36 by depositing a filling layer 50;
(E) planarizing the surface of the filling layer 50;
(F) etching the intermediate layer 44 by etching access points 70 through the intermediate layer sequence 40 by a first etching process; and
(G) exposing the first structural element and the second structural element by etching the first insulation layer 42 and the second insulation layer 46 by a second etching process.

In step (F), sacrificial regions 38 can also be etched in the functional layer 30.

In step (G), the etching stop layer 20 can also be etched, at least in regions.

The method according to the present invention makes it possible to produce micromechanical structures and devices with a high aspect ratio.

The present invention thus creates an electrostatic MEMS electrode pair with a vertical electrode gap having an aspect ratio of >30:1. This allows a micromechanical capacitor structure with high capacitance to be created. A MEMS capacitance of this type can also be composed of a plurality of electrostatic MEMS electrode pairs.

If one of the electrodes is made movable, a capacitor structure with variable electrical capacitance can be produced. This capacitance can be used for both detection and drive purposes.

Thus, the present invention also creates a micromechanical sensor comprising a capacitive measuring probe. The micromechanically produced variable capacitance consists of at least one fixed first electrode and at least one movable second electrode.

The present invention also provides an electrostatic micromechanical actuator comprising at least one micromechanical electrode pair, in particular a so-called NED actuator.

### LIST OF REFERENCE SIGNS

10 Substrate
20 Etching stop layer
30 Micromechanical functional layer
31 First micromechanical structural element, electrode
32 Second micromechanical structural element, electrode
33 Layer thickness
34 Distance, electrode gap
35 Main direction of extent
36 Recess
38 Sacrificial region
40 Intermediate layer sequence
42 First insulation layer
44 Intermediate layer
46 Second insulation layer
50 Filling layer
60 Further layers
70 Etching access point
80 Electrically conductive layer
85 Passivation layer

1-11. (canceled)

12. A method for producing a micromechanical layer structure with a high aspect ratio of a layer thickness to a distance of a first structural element from an adjacent second structural element in a main direction of extent of the layer structure, the method comprising the following steps:
(A) providing a substrate with an etching stop layer arranged on the substrate and a micromechanical functional layer arranged above the etching stop layer;
(B) forming at least one recess in the functional layer by etching as far as the etching stop layer;
(C) depositing an intermediate layer sequence including at least a first insulation layer, an intermediate layer, and a second insulation layer;
(D) filling the recess by depositing a filling layer;
(E) planarizing a surface of the filling layer;
(F) etching the intermediate layer by etching access points through the intermediate layer sequence by a first etching process; and
(G) exposing the first structural element and the second structural element by etching the first insulation layer and the second insulation layer by a second etching process.

13. The method according to claim 12, wherein, after step (D) and before step (F), the filling layer is etched back and a further layer of the filling layer is deposited.

14. The method according to claim 12, wherein after step (E) and before step (F), further layers are deposited on the filling layer and the intermediate layer sequence.

15. The method according to claim 12, wherein, in step (E) or after step (E) and before step (F), the etching access points are produced through the intermediate layer sequence to sacrificial regions in the functional layer.

16. The method according to claim 12, wherein, in step (F), sacrificial regions are etched in the functional layer.

17. The method according to claim 12, wherein, in step (G) or after step (G), the etching stop layer is etched at least in regions and the first structural element and/or the second structural element is made movable.

18. A micromechanical layer structure, having an aspect ratio of a layer thickness to a distance of a first structural element from an adjacent second structural element in a main direction of extent of the layer structure of >30:1.

19. The micromechanical layer structure according to claim 18, wherein a first electrode is formed by the first structural element and a second electrode is formed by the second structural element, and between the first and second electrodes, the distance forms an electrode gap.

20. The micromechanical layer structure according to claim 19, wherein the first electrode and/or the second electrode is movable, and the first electrode and the second electrode form a capacitor with variable electrical capacitance.

21. A micromechanical sensor, comprising:
a capacitive measuring probe including a micromechanical structure having an aspect ratio of a layer thickness to a distance of a first structural element from an adjacent second structural element in a main direction of extent of the layer structure of >30:1.

22. A micromechanical actuator, comprising:
a capacitive drive including a micromechanical structure having an aspect ratio of a layer thickness to a distance of a first structural element from an adjacent second structural element in a main direction of extent of the layer structure of >30:1.
